(19) United States
(12) Patent Application Publication
(10) Pub. No.: US 2026/0328839 A1
(43) Pub. Date: Oct. 22, 2026

(54) OPTICAL ALIGNMENTS IN A TEST SYSTEM

(71) Applicant: Teradyne, Inc., North Reading, MA (US)

(72) Inventors: Brendan Hehir, Somerville, MA (US); David Lewinnek, Reading, MA (US); Coleman Weaver, Nashua, NH (US); Ethan Dwyer, Boston, MA (US)

(73) Assignee: Teradyne, Inc., North Reading, MA (US)

(21) Appl. No.: 19/182,940

(22) Filed: Apr. 18, 2025

(51) Int. Cl. G01R 31/28; G01R 1/073

(52) U.S. Cl. CPC G01R 31/2891; G01R 1/07342

(57) ABSTRACT

An example test system includes a probe card configured to contact a substrate that includes devices under test (DUTs), where the substrate includes a first test site and a second test site corresponding, respectively, to a first DUT and a second DUT; a first module that includes a first fiber optic array configured to align to the first test site; a second module that includes a second fiber optic array configured to align to the second test site; a motion system configured to move the first module relative to the substrate in order to move the first fiber optic array towards alignment with the first test site; and an actuator configured to move the second module relative to the first module in order to move the second fiber optic array towards alignment with the second test site.

### TECHNICAL FIELD

This specification describes example implementations of test systems and processes for implementing optical alignments between fiber optics and test sites on a device under test.

### BACKGROUND

A test system is configured to test the operation of a device. A device tested by a test system is referred to as a device under test (DUT). An example of a type of DUT that may be tested using a test system is a silicon photonic device (SPD). An example SPD is a device manufactured on a substrate, such as a silicon chip or wafer, which is configured to produce, to manipulate, and/or to detect light.

### SUMMARY

An example test system includes a probe card configured to contact a substrate that includes devices under test (DUTs), where the substrate includes a first test site and a second test site corresponding, respectively, to a first DUT and a second DUT; a first module that includes a first fiber optic array configured to align to the first test site; a second module that includes a second fiber optic array configured to align to the second test site; a motion system configured to move the first module relative to the substrate in order to move the first fiber optic array towards alignment with the first test site; and an actuator configured to move the second module relative to the first module in order to move the second fiber optic array towards alignment with the second test site. The test system may include one or more of the following features, either alone or in combination.

The test system may include a fiber optic unit. The fiber optic unit may include the first module and the second module. The fiber optic unit may include one or more additional modules including one or more additional respective fiber optic arrays. The test system may include one or more additional actuators each configured to move a respective one of the one or more additional modules in order to move a respective fiber optic array towards alignment with a respective test site on the substrate.

The motion system may be configured to move the fiber optic unit relative to the probe card to cause the first fiber optic array to contact the first test site and to cause the second fiber optic array to contact the second test site. Contact between the first fiber optic array and the first test site and contact between the second fiber optic array and the second test site may be direct or indirect, e.g., through optical connectors. The motion system may be configured to move the first module in six degrees of freedom that includes movement that is forward/backward (Y axis), up/down (Z axis), left/right (X-axis), yaw (Z-axis rotation), pitch (X axis rotation), and roll (Y axis rotation).

The actuator may include a piezoelectric device connected between the first module and the second module. The actuator may be configured to move the second module in three degrees of freedom that include movement that is forward/backward (Y axis), up/down (Z axis), and left/right (X-axis). The actuator may be configured to move the second module in at least two degrees of freedom including movement that is forward/backward (Y axis) and left/right (X-axis).

The motion system may be configured to move the first module to a resolution of 10 microns or less. The actuator may be configured to move the second module to a resolution of 10 microns or less.

The first module may include one or more first fiber optic cables connected to the first fiber optic array. The second module may include one or more second fiber optic cables connected to the second fiber optic array. The test system may include one or more test instruments in communication with the one or more first fiber optic cables and the one or more second fiber optic cables. The one or more test instruments may be configured to test optical components at test sites on the substrate in parallel through the one or more first fiber optic cables and the more second fiber optic cables.

The test system may include a control system configured to execute a test program to control movement implemented by the motion system and the actuator.

An example method is performed using a test system. The example method may include the following operations: (a) controlling a motion system to move a first module, where the first module includes a first fiber optic array configured to align to a first test site corresponding a first device under test (DUT) on a substrate; (b) controlling the motion system to scan the first module relative to the first DUT to identify a first location on the first DUT that corresponds to a first optical power peak, where the first location corresponds to the first test site on the first DUT; (c) determining that the first optical power peak exceeds a predetermined threshold; (d) controlling an actuator to scan a second module relative to the first module to identify a second optical power peak at a second location on a second DUT on the substrate, where the second location corresponds to a second test site on the second DUT, and where the second module includes a second fiber optic array configured to align to the second test site on the second DUT; (e) determining that the second optical power peak exceeds a predetermined threshold; and (f) performing optical testing on the first DUT and the second DUT in parallel by, concurrently, (i) communicating between the first fiber optic array and the first test site at or near the first location and (ii) communicating between the second fiber optic array and the second test site at or near the second location. The method may include one or more of the following features, either alone or in combination.

Scanning the first module and scanning the second module each may include performing a scan based on a profile. The profile may be sinusoidal and the scan may include a sinusoidal scan. Scanning the first module and scanning the second module may each include performing a gradient scan.

The first module and the second module may be associated with a probe card. The probe card may include an electrical connector configured to mate to a corresponding electrical connector on the first DUT. The method may include controlling the probe card to move toward the substrate to cause the electrical connector on the probe card to mate to the corresponding electrical connector on the first DUT. Operations (a) to (f) may be performed after the electrical connector on the probe card mates to the corresponding electrical connector on the first DUT.

The first module and the second module may be components of a fiber optic unit. The method may include positioning the fiber optic unit a predefined distance above the DUT. The positioning may include using one or more capacitive sensors to obtain a voltage corresponding to a distance of the fiber optic unit above the substrate, and comparing the voltage obtained to the predefined voltage.

Operations (a) to (f) may be performed automatically without human intervention.

The method may include controlling the motion system to move the first module toward alignment with the first location prior to performing operations (d), (e), and (f); and controlling the actuator to move the second module toward alignment with the second location prior to performing operation (f).

The method may include, prior to performing operation (f), controlling the motion system to move the first module and the second module towards the DUT so that the first fiber optic array is connected (either directly or indirectly) to the first test site and so that the second fiber optic array is connected to the second test site

The method may include storing, in memory and in parallel, values for the first peak optical power and the second peak optical power in association with one or more respective site-aware variables.

Any two or more of the features described in this specification, including in this summary section, may be combined to form implementations not specifically described in this specification.

At least part of the devices, circuitry, systems, techniques, and processes described in this specification may be implemented or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, circuitry, systems, techniques, and processes described in this specification may be implemented or controlled using a computing system comprised of one or more processing devices and memory storing instructions that are executable by the one or more processing devices to perform various control operations. The devices, circuitry, systems, techniques, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a block diagram of an example test system configured to align fiber optics on the test system to test sites of devices under test (DUT).

FIG. 2 is a bottom, perspective view of components included in an example probe head in an example implementation of the test system of FIG. 1.

FIG. 3 is a partial, top view of components included in an example probe card in an example implementation of the test system of FIG. 1

FIG. 4 is a top, perspective view of components included in an example probe card in an example implementation of the test system of FIG. 1.

FIG. 5 is a flowchart containing operations included in an example process for aligning fiber optics on the test system to multiple test sites.

FIG. 6 is a graph showing measurement of optical signal power.

FIG. 7 is a block diagram of a top view of example shafts of four modules that are controllable to align fiber optics to test sites.

FIG. 8 is a block diagram of a top view of components of example shafts of four modules that are controllable to align fiber optics to test sites.

FIG. 9 is a block diagram of an example test system configured to incorporate the components shown in FIGS. 1 to 5.

Like reference numerals in different figures indicate like elements.

### DETAILED DESCRIPTION

Described herein are example implementations of systems and processes configured to test optical devices, such as silicon photonic devices (SPDs). SPDs include components that leverage the optical properties of silicon to perform various functions in photonic integrated circuits (PICs). An example SPD may be or include a device manufactured on a silicon chip or wafer, which is configured to produce, to manipulate, and/or to detect light. Examples of SPDs may include, but are not limited to, laser diodes, light-emitting diodes (LEDs), solar and photovoltaic cells, displays, fiber optic transceivers, optical amplifiers, waveguides, modulators, and detectors.

An SPD that is being tested by a test system is a device under test (DUT). Multiple SPDs may be formed on a substrate, such as a single silicon chip or wafer, and separated therefrom after testing. Accordingly, in some implementations, the substrate, such as the silicon chip or wafer, may be considered to be the DUT.

An example SPD on a silicon chip or wafer includes an optical interface, such as an optical connector, which constitutes a test site on the silicon chip or wafer at which optical testing of the SPD is performed. Accordingly, this optical interface is referred to herein as an “SPD test site”. The SPD test site may optically connect to, and thus provide an external interface to, internal optical components on the SPD, such as one or more optical fibers or waveguides. The SPD test site may be part of an optical-electrical interface, which may also enable electrical connection to electrical parts of optical components on the SPD, such as the electrical leads of an LED.

The SPD test site is configured to optically connect to fiber optics of a test system, which is referred to as the “tester fiber optics”. The tester fiber optics may be or include a fiber optic array optically connected to one or more fiber optic cables. An example fiber optic array includes multiple optical fibers arranged in a specific configuration to enable light transmission and signal processing. Such an array may be designed to handle high data rates. The fibers in the array may be aligned and bundled together to enhance performance and to reduce signal loss. Each fiber within the array may act as a conduit for light, transmitting data over distances with, in some examples, high fidelity and low latency. The array configuration can vary, including linear, circular, or custom patterns, depending on the application requirements.

Connection between the SPD test site and the tester fiber optics may be or include a direct connection. For example, an optical connector coupled to the fiber optic array on the tester may physically connect to a complementary optical connector coupled to the test site on the SPD. Connection between the SPD test site and the tester fiber optics may be or include an indirect connection. For example, there may be one or more intermediary optical components, which enable transmission of light, between the above optical connector for the fiber optic array and complementary optical connector on the SPD. Connection between the SPD test site and the tester fiber optics need not include a physical connection. For example, the tester fiber optics may align to the optical interface on the SPD with an air gap between them that enables optical communication between the fiber optic array and the optical interface. This optical communication over the air gap may constitute a connection between the SPD test site and the tester fiber optics for the purposes of the example systems and processes described herein.

The optical connection between the SPD test site and the tester fiber optics creates an optical path over which optical signals can pass between the SPD and the test system. Optical signals from the test system to the SPD, which are referred to as test signals, may be used to test the SPD. For example, the intensity, polarity and/or wavelength of optical signals may represent data to be processed by the SPD or may represent parameters of voltage or current to be applied to the SPD, for example, to illuminate an LED. Optical signals from the SPD to the test system, which may be referred to as response signals, may represent data or parameters that are produced by operation the SPD, including in response to received signals to test the SPD.

SPD test sites for different DUTs may be at different locations. The systems and processes described herein are therefore configured to move tester fiber optics relative to SPDs in order to align the tester fiber optics to SPD test sites. The systems and processes described herein may be used to finely align tester fiber optics to the SPD test sites. For example, a probe card containing, or associated with, the tester fiber optics may also connect electrically to the SPD. Deviations in placement of the SPD test sites relative to these electrical connections may be accounted for by moving the tester fiber optics relative to the SPD to align the tester fiber optics to the SPD test sites. In some implementations, alignments of tester fiber optics to SPD test sites may be achieved by moving the tester fiber optics by ten microns (μm or micrometers) or less, or by less than one micron, that is, sub-micron. In some implementations, alignments of the tester fiber optics to the SPD test sites may be achieved by moving the tester fiber optics tens of microns or more. Any amount of movement may be made to achieve alignment. In this regard, as used herein, an optical alignment may include deviations from precise alignment that still enable transmission of optical signals sufficient for electrical testing to pass between the test system and the SPDs. For example, alignments that deviate from perfect alignment by 1%, 2%, 3%, 5%, 10% or more, may be acceptable in some implementations.

The systems and processes described herein are configured to enable parallel optical testing of SPDs. In some implementations, parallel optical testing includes sending test signals concurrently to two or more SPDs on a silicon chip or wafer and receiving, from the two or more SPDs, responses to those test signals. The test system may then process the responses concurrently to determine whether the SPDs passed or failed testing and bin the SPDs accordingly. To implement parallel optical testing, the systems and processes described herein align tester fiber optics to multiple SPD test sites. This may be done by using a motion system to align a first module including first tester fiber optics, such as a fiber optic array, to a first SPD test site and using an actuator to align a second module including second tester fiber optics, such as a fiber optic array, to a second SPD test site. The actuator may be or include a piezoelectric actuator that is connected between the first module and the second module. In this example, the first module and the second module are physically coupled, so that the motion system moves both modules when aligning the first module. After the first module is aligned, the actuator is controlled to move the second module relative to the first module (and relative to the SPD and silicon chip or wafer) in order to align the second tester fiber optics to the second SPD test site. After the first tester fiber optics is aligned to the first test stie and the second tester fiber optics is aligned to the test site, respective optical connections are or may be created and parallel testing of first and second SPDs at the first and second SPD test sites, respectively, is performed.

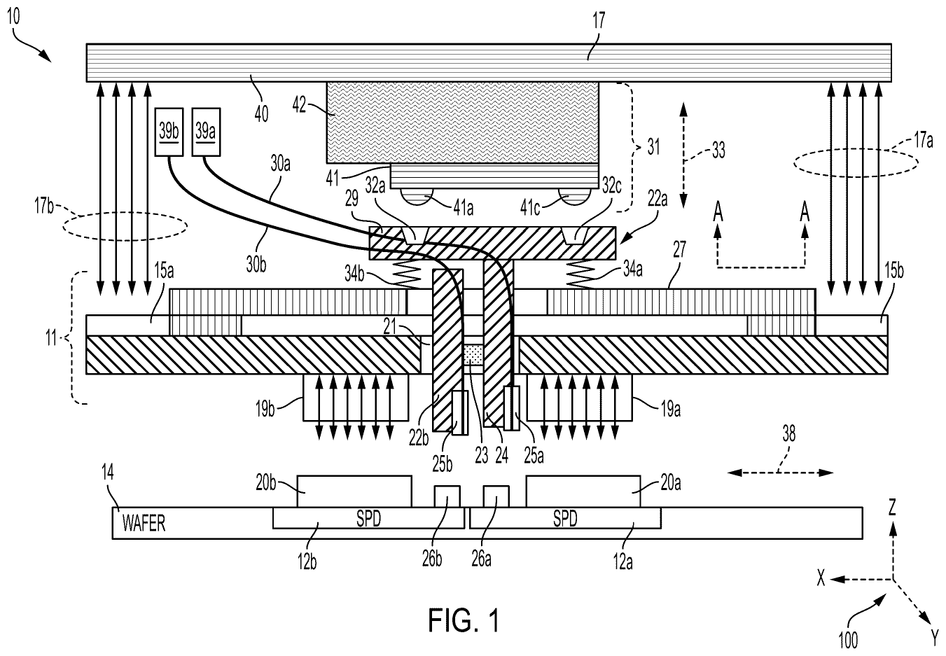

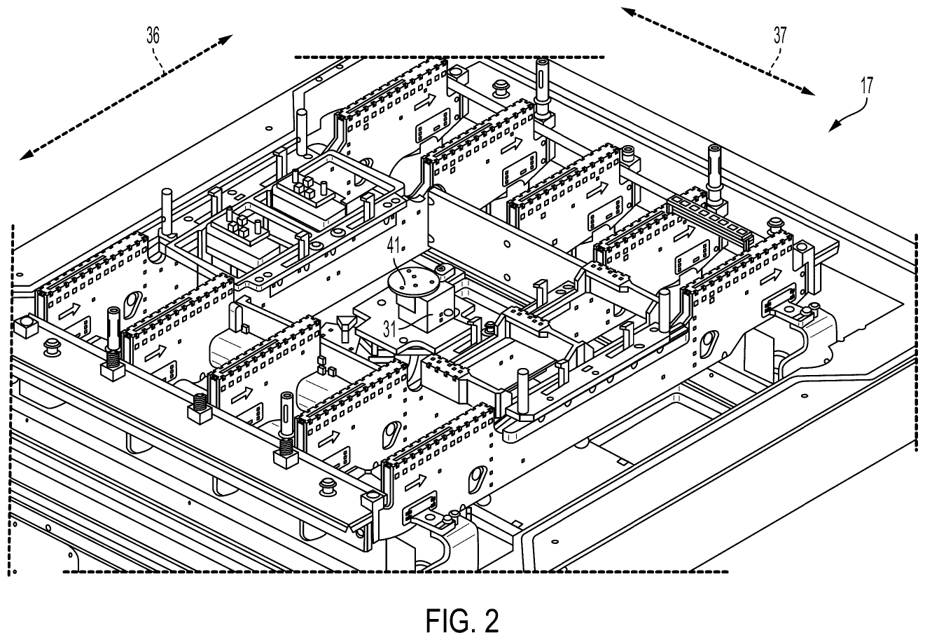

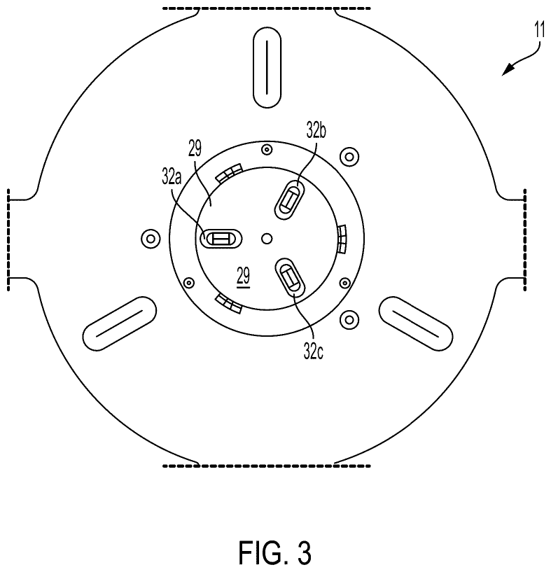

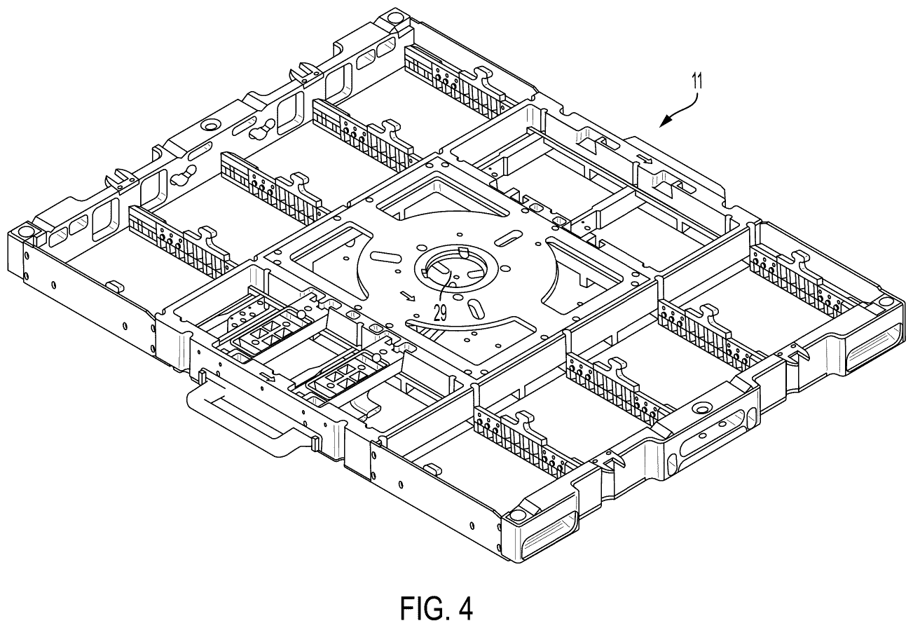

FIG. 1 is a block diagram of example components of an example test system 10 of the type described above. FIG. 2 shows, in perspective, a bottom view of part of an example probe head containing components of an implementation of test system 10. FIG. 3 is a top view of part of an example probe card containing components of an implementation of test system 10. FIG. 4 shows, in perspective, a top view of an example probe card containing components of an implementation of test system 10.

Referring to FIG. 1, test system 10 includes a probe card 11 configured to contact test sites for SPDs 12a, 12b on wafer 14. SPDs 12a, 12b may be instances of any type of SPD, examples of which are described above. An example probe card includes electrical and mechanical interfaces that enable testing operation of a device while the device is still part of wafer 14. Probe card 11 may be a printed circuit board (PCB) or other structure configured to provide electrical connection between SPDs 12a, 12b and test electronics in probe head 17. For example, probe card 11 may include one or more conductive layers and vias configured the pass electrical signals between the SPD and test electronics. Probe card 11 may include one or more passive and/or active electronic devices to condition, to process, and/or route electrical signals.

Probe card 11 may include electrically-conductive pads or electrical connectors 15a, 15b configured to accept, and to electrically connect to, one or more electrical connectors, lines, or cables 17a, 17b from test electronics in probe head 17. Probe card 11 also includes one or more electrically-conductive pads or electrical connectors 19a, 19b configured to electrically connect to corresponding electrically-conductive pads or electrical connectors 20a, 20b on respective SPDs 12a, 12b. The resulting electrical connections create an electrical pathway from SPDs 12a, 12b, through probe card 11, to test electronics in probe head 17. Electrical signals may pass between SPD 12a, 12b and the probe head over these electrical pathways during individual or parallel testing of SPDs 12a, 12b.

In this example, probe card 11 also includes a through-hole 21 to accommodate part of first module 22a and part of second module 22b. As described below, module 22a is a structure having a shaft 24 configured to hold tester fiber optics 25a, such as a fiber optic array which may or may not include an optical connector, and to move tester fiber optics 25a relative to SPD 12a and SPD test site 26a. As described below, module 22b is a structure which may be or include a shaft to hold tester fiber optics 25b, such as a fiber optic array which may or may not include an optical connector, and which is configured to move tester fiber optics 25b relative to SPD 12b and SPD test site 26b.

Through-hole 21 may pass entirely through probe card 11 to allow shaft 24 of module 22a and the shaft of module 22b (“the shafts”) to pass through probe card 11 so that tester fiber optics 25a, 25b can optically connect to respective SPD test site 26a, 26b on respective SPDs 12a, 12b. Through-hole 21 may be circular in shape. The dimensions of through-hole 21 may be based on the amount of movement needed for the shafts to move within probe card 11 and the size of the shafts. For example, through-hole 21 may have a diameter on the order of single-digit centimeters or single-digit millimeters. Such dimensions may accommodate the shafts and, some cases additional shafts, and enable movement of the shafts within through-hole 21 in a range of single-digit microns (μm) or less. Such dimensions may also enable movement of the shafts within through-hole 21 in a range of single-or double-digit millimeters or more to enable optical alignments between tester fiber optics 25a and SPD test site 26a and between tester fiber optics 25b and SPD test site 26b.

In some implementations, probe card 11 includes a support structure 27. Support structure 27 may be connected physically to probe card 11 and, in some cases, need not include electrical connections to probe card 11. As shown, in this example, support structure 27 is elevated relative to the rest of probe card 11 to support a part 29 of module 22a that interfaces to a motion system 31. Support structure 27 may be elevated relative to the rest of probe card 11 to prevent damage to structures, such as passive and/or active electronic devices, on probe card 11 under support structure 27. In some cases, such damage could, in the absence of support structure 27, occur during movement of module 22a relative to wafer 14 and the SPDs, as described below.

In some implementations, modules 22a and 22b are considered to be part of probe card 11. In some implementations, modules 22a and 22b are separate from, but used with, probe card 11. In either case, modules 22a and 22b are associated with probe card 11 and its operation. In some implementations, modules 22a and 22b constitute, or are part of, or are integrated into, a fiber optic unit or fiber optic array. Accordingly, in some implementations, modules 22a and 22b are physically coupled together such that movement of module 22a described herein results in corresponding-for example, identical-movement of module 22b, which includes vertical, horizontal, and/or angular movements. The physical coupling may include, but is not limited to, an actuator 23 connected between, and to, each of modules 22a and 22b. Examples of the structure and function of the actuator are described below.

In the example of FIG. 1, module 22a includes system interface 29 physically connected to shaft 24. In this example, system interface 29 and shaft 24 are orthogonal to each other; however, in other implementations, the angle between system interface 29 and shaft 24 may be oblique. As noted, shaft 24 holds tester fiber optics 25a. Tester fiber optics 25a may be connected to, or an integral part of (for example, formed as part of), shaft 24. As a result, tester fiber optics 25a does not move relative to shaft 24, but rather moves along with movement of shaft 24.

Tester fiber optics 25a is configured to optically connect fiber optics, such as one or more fiber optic cables 30a, to corresponding SPD test site 26a. As noted above, in some implementations, this optical connection may be implemented using optical connectors at tester fiber optics 25a and SPD test site 26a. Examples of types of optical connectors that may be used for tester fiber optics 25a and corresponding SPD test site 26a include, but are not limited to, ST (straight tip) connectors, SC (standard connector) connectors, LC (Lucent® connector) connectors, 10G-CX4 connectors, Infiniband™ (4x) connectors, MTRJ (mechanical transfer-registered jack (connectors), MTP/MPO connectors, RJ-45 (registered jack-45) connectors, D4 connectors, ESCON (enterprise systems connection) connectors, opti-jack connectors, FDDI (fiber distributed data interface) connectors, MU (multi-termination unibody) connectors, CS® connectors, or SN® compact connectors.

In some implementations, tester fiber optics 25a may include silicon in which optical structures, which make optical connection to SPD test site 26a, are set. In some implementations, tester fiber optics 25a may include glass in which optical structures, which make optical connection to SPD test site 26a, are set.

Shaft 24 may be hollow or partially hollow with a through-hole therein to receive and to hold part of fiber optic cable(s) 30a. In this regard, an example fiber optic cable 30a includes one or more optical fibers, e.g., either single mode, multimode, polarization-maintaining, or a mixture of the three, over which optical signals pass. Fiber optic cable(s) 30a connect optically to tester fiber optics 25a so that optical signals can pass between fiber optic cable(s) 30a and test site 26a via an optical connection between tester fiber optics 25a and SPD test site 26a. Shaft 24 may hold fiber optic cable(s) 30a tightly or loosely. For example, when fiber optic cable(s) 30a are held tightly, fiber optic cable(s) 30a do not move through or relative to shaft 24. For example, when fiber optic cable(s) 30a are held loosely, fiber optic cable(s) 30a may move through or relative to shaft 24.

Module 22a also includes system interface 29. System interface 29 is so named because it is the part of module 22a that mechanically interfaces to motion system 31, described below. In some implementations, system interface 29 is a plate or other flat structure containing indentations that are configured for mating to motion system 31. In some implementations, system interface 29 need not be flat but rather may have any shape that is complementary to the part of motion system 31 that mates to module 22a or that enables that part of the motion system to mate to module 22a.

System interface 29 may be hollow or partially hollow with a through-hole therein to receive and to part of hold fiber optic cable(s) 30a. Accordingly, fiber optic cable(s) 30a pass through both shaft 24 and system interface 29. System interface 29 may hold fiber optic cable(s) 30a tightly or loosely. For example, when fiber optic cable(s) 30a are held tightly, the fiber optic cable do not move through or relative to system interface 29. For example, when fiber optic cable(s) 30a are held loosely, the fiber optic cables may move through or relative to system interface 29.

As shown in FIG. 1, fiber optic cable(s) 30a may terminate in an optical connector 39a that is configured to connect to, and to disconnect from, a backplane 40 of probe head 17. The connection and disconnection may enable connection to different test instruments in the test system, examples of which are described herein. Testing of the SPD may be performed over the resulting optical connection.

Referring also to FIGS. 2, 3, and 4, system interface 29 may be circular or have any other appropriate shape viewed along A-A or its inverse. System interface 29 may have multiple indentations arranged around a radius thereof or at any other appropriate locations on system interface 29. In the example of FIGS. 3 and 4 system interface 29 includes three indentations 32a, 32b, and 32c; however, other implementations may contain more than three indentations or fewer than three indentations; for example, one, two, four, five, six, and so forth indentations. The indentations may have shapes that complement or accommodate shapes of protrusions on motion system 31, as described below. In the example of FIGS. 3 and 4, the indentations have a stadium shape in lateral or horizontal cross-section, which is a rectangle with round ends. However, in other implementations, the indentations may have shapes that include, but are not limited to, round, oval, oval or circular ending in a pointed V-shape at one end, elliptical, or rectangular in lateral or horizontal cross-section. In some implementations, the longitudinal or vertical cross-section of module 22a of FIG. 1 is generally “T”-shaped.

In module 22b, tester fiber optics 25b is configured to optically connect fiber optics, such as one or more fiber optic cables 30b, to corresponding SPD test site 26b. As noted above, in some implementations, this optical connection may be implemented using optical connectors at tester fiber optics 25b and SPD test site 26b. Examples of types of optical connectors that may be used include those described above.

In some implementations, tester fiber optics 25b may include silicon in which optical structures, which make optical connection to SPD test site 26b, are set. In some implementations, tester fiber optics 25b may include glass in which optical structures, which make optical connection to SPD test site 26b, are set.

The shaft that makes up or is part of module 22b may be hollow or partially hollow with a through-hole therein to receive and to hold part of fiber optic cable(s) 30b. As above, an example fiber optic cable 30a includes one or more optical fibers, e.g., either single mode, multimode, polarization-maintaining, or a mixture of the three, over which optical signals pass. Fiber optic cable(s) 30b connect optically to tester fiber optics 25b so that optical signals can pass between fiber optic cable(s) 30b and test site 26b via an optical connection between tester fiber optics 25b and SPD test site 26b. The shaft may hold fiber optic cable(s) 30a tightly or loosely. For example, when fiber optic cable(s) 30b are held tightly, fiber optic cable(s) 30b do not move through or relative to the shaft. For example, when fiber optic cable(s) 30b are held loosely, fiber optic cable(s) 30b may move through or relative to the shaft.

Fiber optic cable(s) 30b pass through both module 22b and system interface 29. System interface 29 may hold fiber optic cable(s) 30b tightly or loosely. For example, when fiber optic cable(s) 30b are held tightly, the fiber optic cable do not move through or relative to system interface 29. For example, when fiber optic cable(s) 30b are held loosely, the fiber optic cables may move through or relative to system interface 29.

As shown in FIG. 1, fiber optic cable(s) 30b may terminate in an optical connector 39b that is configured to connect to, and to disconnect from, a backplane 40 of probe head 17. The connection and disconnection may enable connection to different test instruments in the test system, examples of which are described herein. Testing of the SPD may be performed over the resulting optical connection.

In some implementations, in an unactuated state-that is, before any movement of the modules, module 22b is vertically (e.g., in the dimension of arrow 33) displaced downward relative to shaft 24a such that downward movement of system interface 29 causes system interface 29 to contact module 22b and thereby produce vertical movement of module 22b while bringing tester fiber optics 25a and 25b into vertical alignment. In some implementations, module 22b is connected to system interface 29 (not shown) with tester fiber optics 25a and 25b being vertically aligned in both the unactuated state and the actuated state.

The physical coupling between module 22a and 22b includes actuator 23. Actuator 23 may be a piezoelectric actuator. An example piezoelectric actuator is a device that operates by exploiting the piezoelectric effect, which is a phenomenon where certain materials generate mechanical strain in response to an applied electric field. When voltage is applied to a piezoelectric material, such as quartz or specific ceramics, the material undergoes a change in shape or size, producing precise mechanical movement. This transformation is due to the alignment of electric dipoles within the material, which causes it to expand or contract. An example design for the piezoelectric actuator may include includes a stack or layer of piezoelectric elements, which amplifies the movement and allows for greater displacement.

Actuator 23 is controlled to cause module 22b, and thus tester fiber optics 25b, to move relative to module 22a—and thus also to move relative to wafer 14, SPD 12b, and test site 26b—in order to align tester fiber optics 25b to test site 26b following alignment of tester fiber optics 25a to test site 26a. By controlling the voltage applied to the piezoelectric actuator 23, the piezoelectric actuator may position module 22b relative to module 22a at the micron or sub-micron level.

The movement produced by actuator 23 may include horizontal movement (e.g., in the directions of arrow 38) of module 22b relative to module 22a. The movement implemented actuator may be produced while module 22a is stationary. In some implementations, the movement produced by actuator 23 may include linear motion that is forward/backward (Y axis—into and out of the page), up/down (Z axis), and left/right (X-axis) 100. In some implementations, the movement produced by actuator 23 may include angular movement such as pitch, yaw, and roll described herein.

As shown in FIG. 1, system 10 may include one or more springs 34a, 34b between system interface 29 and support structure 27 of probe card 11. In some implementations, there are three springs located at roughly the same radius as the indentations but on the opposite surface of system interface 29 from the indentations. However, this is not a requirement and the springs may be at any appropriate locations. As shown, springs 34a, 34b bias system interface 29 above probe card 11 and enable movement of modules 22a and 22b in multiple degrees of freedom. That is, springs 34a, 34b bias system interface 29 to a position above probe card 11 that is imposed by the spring load. In some implementations, springs 34a, 34b are connected to support structure 27 in such a way as to enable movement of modules 22a, and thus of module 22b, in six degrees of freedom relative to SPDs 12a, 12b, which include forward/backward, up/down, left/right, yaw, pitch, and roll. For example, the springs may slide across the surface of support structure 27 or within tracks (not shown) on support structure 27. Because support structure offset relative to the rest of the probe card, this movement will not damage circuitry or components on the probe card.

Referring to FIG. 1, the up/down movement along arrows 33 enables creation of an optical connection between tester fiber optics 25a and SPD test site 26a and between tester fiber optics 25b and SPD test site 26b. Referring to FIG. 2 forward/backward and left/right movement along arrows 36 and 37, respectively, enables movement of modules 22a, 22b relative to SPDs 12a, 12b and, thus, of tester fiber optics 25a, 25b relative to SPD test sites 26a, 26b to achieve alignments for the optical connections. The yaw, pitch, and roll movements may facilitate creation of the optical connection between tester fiber optics 25a, 25b and SPD test site 26a, 26b by enabling, e.g., additional force to be applied to part of tester fiber optics 25a, 25b.

Referring back to FIG. 1, motion system 31 is configured to move into, and out of, contact with module 22a in the directions of arrows 33, e.g., through movement of the motion system alone or in response to movement of part of probe head 17 relative to probe card 11. When motion system 31 is in contact with module 22a, motion system 31 is configured to move module 22a relative to SPD 12a in order to align tester fiber optics 25a to the SPD test site 26a. Because module 22b is physically coupled to module 22a, when motion system 31 is in contact with module 22a, motion system 31 is also configured to move module 22b relative to SPD 12b in order to align tester fiber optics 25b to the SPD test site 26b, at least partly. To this end, motion system 31 includes a connecting structure 41, such as a plate.

Referring also to FIG. 2, connecting structure 41 may be circular or have any other appropriate shape. Connecting structure 41 includes protrusions that mate to complementary indentations on system interface 29. In some implementations, connecting structure 41 may have multiple protrusions arranged around a radius thereof. In the example of FIG. 1, connecting structure 41 includes three protrusions (only 41a, 41c shown in FIG. 1); however, other implementations may contain more than three protrusions or fewer than three protrusions; for example, one, two, four, five, six, and so forth protrusions. The protrusions may have shapes and locations that complement the shapes and locations of indentations on system interface 29, as noted above. In some implementations, the protrusions have a stadium shape in lateral or horizontal cross-section, which is a rectangle with round ends. However, in other implementations, the protrusions may have shapes that are, but are not limited to, round (e.g., ball-shaped), oval, elliptical, oval or circular with a V-shape at one end, or rectangular in lateral or horizontal cross-section.

In some implementations, motion system 31 includes robotics that are controllable to cause connecting plate to move in the six degrees of freedom. For example, the motion system described below may be configured to move module 22a in at least six degrees of freedom relative to wafer 14 and SPD 12a including motion that is forward/backward (Y axis), up/down (Z axis), left/right (X-axis), yaw (Z-axis rotation), pitch (X axis rotation), and roll (Y axis rotation). In some implementations, the motion system may be configured to move module 22a in at least three degrees of freedom relative to wafer 14 and SPD 12a including at least forward/backward (Y), left/right (X), and theta. This movement is along two linear axes (X and Y) and rotational movement around a perpendicular axis (theta). The theta axis adds rotational capability, allowing the object or platform to rotate around a central point.

In some implementations, the actuator may be configured to move module 22a in at least three degrees of freedom relative to wafer 14, SPD 12a, and module 22a including at least forward/backward (Y), left/right (X), and theta, where theta movement is as defined above. In this regard, X, Y, theta movement refers to a three-degree-of-freedom motion system. In some implementations, the actuator may be configured to move module 22a in at least three degrees of freedom relative to wafer 14, SPD 12a, and module 22a including at least forward/backward (Y), left/right (X), and up/down (Z). In some implementations, the actuator may be configured to move module 22a in at least two degrees of freedom relative to wafer 14, SPD 12a, and module 22a including at least forward/backward (Y) and left/right (X). In some implementations, the actuator may be configured to move module 22a in two degrees of freedom relative to wafer 14, SPD 12a, and module 22a which are forward/backward (Y) and left/right (X) but not up/down (Z). X and Y movement provide horizontal and vertical linear translation, enabling positioning in a two-dimensional plane. X, Y, and Z movement provide three orthogonal linear translations, enabling positioning in a three-dimensional space.

In some implementations, the robotics include a housing 42 that holds one or more motors configured to move connecting structure 41 relative to system interface 29 in the six degrees of freedom described previously. Motion system 31 may be implemented using electrical control or pneumatic control in some implementations.

In some implementations, system interface 29 is or includes a first plate and connecting structure 41 is or includes a second plate. The first plate and the second plate may be magnetically attracted to each other to create and/or to hold or supplement a connection of the first plate and the second plate in order to enable movement of module 22a relative (e.g., towards or away from) to probe card 11 and SPD 12a and in order to enable movement of module 22b relative (e.g., towards or away from) to probe card 11 and SPD 12b. In some implementations, the first plate and the second plate include components to implement a mechanical latch to hold the first plate and the second plate together in order to enable movement of module 22a relative to probe card 11 and SPD 12a and in order to enable movement of module 22b relative (e.g., towards or away from) to probe card 11 and SPD 12b. In some implementations, at least one of the first plate or the second plate is connected to a suction device (not shown) configured to apply suction through the plate to the other plate to hold the first plate and the second plate together in order to create and/or to hold or supplement a connection the first plate and the second plate in order to enable movement of module 22a relative to probe card 11 and the SPD 12a and in order to enable movement of module 22b relative (e.g., towards or away from) to probe card 11 and SPD 12b.

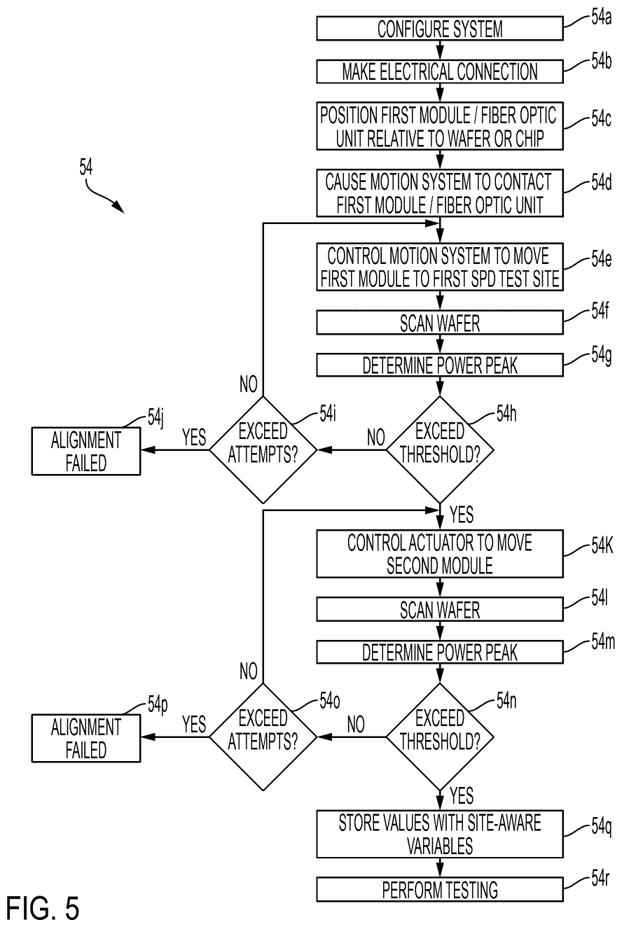

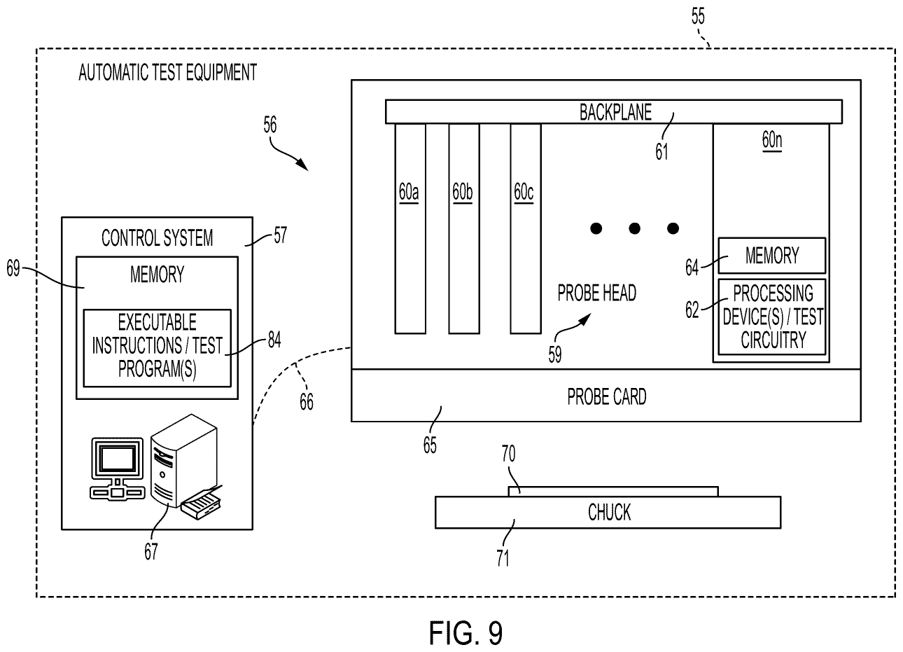

FIG. 5 is a flowchart showing operations included in an example process that may use test system 10 (FIG. 1) and variants thereof described herein. The operations of process 54 may be controlled by, or performed by, a control system and/or test instrument(s) of the test system, such as those described below with respect to FIG. 9.

Process 54 includes configuring (54a) the test system. This may include programming the control system with operational parameter, which may be DUT-specific. Examples of these parameters include, but not limited to, wavelengths of optical signals used during testing, optical power thresholds, the locations of all SPDs on wafer 14, the locations of all electrically-conductive pads or electrical connectors on all SPDs of wafer 14, the expected locations of all test sites on wafer 14, the dimensions of a region of wafer 14 to be scanned, the number of times to attempt alignment, and the distance to position the fiber optic unit above the substrate. In some implementations, the locations may include coordinates of a coordinate system superimposed over the wafer by the control system. The configuration process may also include controlling switching to connect power to the motion system 31.

Process 54 includes making an electrical connection (54b) between the probe card 11 and the electrically-conductive pads or electrical connectors 20a, 20b on the respective SPDs 12a, 12b. The control system may control a motor, an actuator, or other movement mechanism (not shown) to move probe card 11 towards wafer 14 so as to implement the electrical connections of 12a-20a and 12b-20b.

Process 54 includes positioning (54c) modules 22a, 22b a predefined distance above wafer 14. This predefined distance may be on the order of single digit centimeters or more or less. The predefined distance may be device specific and may be set to enable optical communication between the test system and the fiber optic unit absent physical connection. Positioning may be performed by the control system controlling a fiber optic unit containing modules 22a, 22b to move relative to the wafer. The control system may control a motor, an actuator, or other movement mechanism (not shown) to move the fiber optic unit towards or away from the wafer 14. The fiber optic unit may include one or more capacitive sensors (not shown) to obtain a voltage corresponding to a distance of the fiber optic unit above the wafer. For example, the fiber optic unit may include one capacitive sensor for each array of fibers. The voltage may be sent to the control system, which may compare the obtained voltage to a predefined voltage representing a predefined distance to the wafer. The voltage may be obtained and compared to the predefined voltage until the difference between the two is within an acceptable tolerance, e.g., there is a 10% or less difference between the two, a 5% or less difference between the two, a 3% or less difference between the two, a 2% or less difference between the two, or a 1% or less difference between the two. Once the difference between the two is within an acceptable tolerance, the control system knows that the fiber optic unit is at a desired distance above wafer 14.

In some implementations, there may be multiple fiber optic units containing instances of modules 22a and 22b associated with a probe card and operable as described herein. Each fiber optic unit may include its own distance sensor.

In some implementations, optical fibers of a fiber array may be used to perform the distance sensing. For example, a fiber optic unit may include a light source configured to output light; a photodetector to receive a reflection of the light; and an optical fiber that is optically coupled to the light source and the photodetector. An end of the optical fiber or a microlens at the end of the optical fiber is configured to output the light from the light source to the DUT or wafer to produce the reflection of the light. The distance between the fiber optic unit and substrate or DUT on the substrate is determined based on the reflection. Implementations of distance sensors of this type that can be used to detect the distance between the fiber optic unit and substrate or DUT on the substrate are described in U.S. Provisional Application No. 63/753,523 field on Feb. 4, 2025 and titled “Performing Detection On A Target Device. The contents of U.S. Provisional Application No. 63/753,523 are incorporated by reference into this application, particularly with respect to the distance sensing optical channels described with respect to FIGS. 2 to 8 of U.S. Provisional Application No. 63/753,523.

Process 54 may include causing (54d) the motion system to contact the fiber optic unit, in particular, first module 24a. For example, the control system may control one or more motors or robotics that are part of the motion system so that protrusions 41a, 41c mate to respective indentations 32a to 32c on first module 22a.

Process 54 may include causing (54e) the motion system to move the fiber optic unit/first module 22a into an expected alignment with test site 22a. The control system may control the motion system so that the fiber optic unit/first module 22a is over the location of test site 24a. This location of test site 24a on wafer 14 is programmed into the control system in the configuration operation (54a) and, therefore, is the location that is expected to produce alignment between tester fiber optics 25a on module 22a and test site 26a. However, due to process variations in the wafer or other factors, the expected location that produces alignment may not be the correct location that produces alignment. Accordingly, the location of module 22a may be adjusted to bring module 22a at or close to the exact location that produces alignment with the test site, or at least into an alignment that enables optical testing to be performed on the SPD. The movement may be in the X, Y, Z, pitch, yaw, and/or roll degrees of freedom in some implementations.

Process 54 includes optically scanning (54f) a local region around test site 24a on wafer 14. The local region may be tens (e.g., 20) of microns square or in area, or less in some implementations. The control system may control the motion system to move the first module 24a to implement the scanning. The scanning may include scanning based on a profile. The profile may be stored in memory and indicative of any type of curve, such as a sinusoid. Accordingly, the scanning may include sinusoidal scanning and gradient scanning. The scanning includes moving first module 24a around the scanning area, first module 24a outputting optical signals from tester fiber optics 25a during movement, tester fiber optics 25a receiving optical signals in response to the output optical signals, and the control system measuring optical power from the SPD that is produced based on the received optical signals.

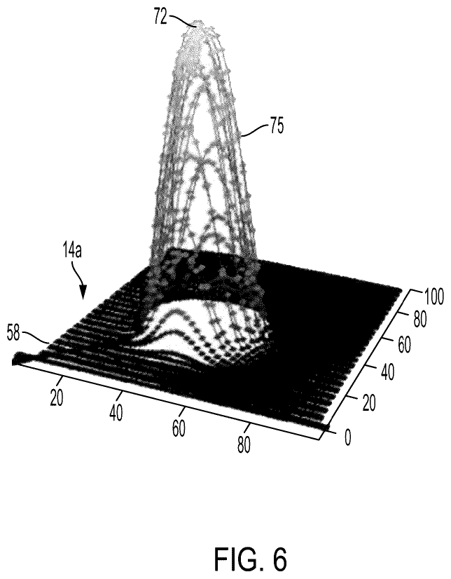

In an example, the sinusoidal optical scan operates by modulating the position of an optical beam in a smooth, periodic manner that follows a sinusoidal waveform. The frequency and amplitude of the sinusoidal motion are controlled by an input signal from the control system, allowing precise adjustments to match the specific requirements of the application. The sinusoidal pattern allows the beam to move with a consistent speed, reducing mechanical stress and providing uniform coverage across the scanned area. In an example, the gradient optical scan includes a controlled movement of an optical beam across the surface of the wafer, where the scanning speed or intensity varies according to a predefined gradient. During the scan, the beam's speed or intensity is modulated to create a gradual change, allowing for detailed analysis or processing of the scanned area. This modulation is achieved through control of the scanning device, which adjusts the beam's parameters in real-time based on input signals. FIG. 6 shows a path 58 along an area 14a of the wafer being scanned and corresponding optical powers. As shown, the scans reveal a power peak 72, which is the maximum optical power produced by the SPD at a scanned location.

The control system may determine (54g) the location of the power peak by comparing newly-received optical powers to previously-received optical powers and identifying which are greater. The power peak corresponds to the scanning location on the wafer having the greatest optical power. The optical power scan results are obtained for discrete points 74, so the control system may perform interpolation among those points to determine (54g) the location of power peak 72.

Process 54 includes determining (54h) whether the peak optical power determined in operation 54g exceeds a predefined threshold. The control system may compare the peak optical power to the threshold. The threshold is programmed into the control system and may represent a minimum optical power needed to perform optical testing for SPD 12a. If the peak optical power determined in operation 54g does not exceed the predefined threshold, the control system determines (54i) whether the number of attempts at alignment have exceeded a predefined threshold. If the number of attempts at alignment have exceeded a predefined threshold, the control system determines (54j) that alignment has failed. In that case, manual intervention may be needed and/or system setting may be reprogrammed in operation 54a. If the number of attempts at alignment have not exceeded a predefined threshold (54i), the control system repeats operations 54e to 54i until the threshold is exceeded in operation 54h, meaning that peak optical power is sufficient for optical testing, or until the number of attempts at alignment have exceeded a predefined threshold in operation 54j.

If the peak optical power determined in operation 54g exceeds a predefined threshold (54h), this means that the location to which the first optical module 22a was moved in operation 54e brings tester fiber optics 25a into acceptable alignment with test site 26a to perform optical testing on SPD 12a. Accordingly, from this point forward in process 54, first module 22a is controlled by the control system to remain stationary.

When the peak optical power determined in operation 54g exceeds a predefined threshold (54h), process 54 proceeds to operation 54k. In operation 54k, the control system controls piezoelectric actuator 23 to move module 22b, and thus tester fiber optics 25b, relative to module 22a. Although the control system controls piezoelectric actuator 23 to move module 22b, and thus tester fiber optics 25b, relative to the entirety of module 22a, the relevant motion here is with respect to shaft 24 of module 22a. Accordingly, another way to explain this is that the control system controls piezoelectric actuator 23 to move module 22b, and thus tester fiber optics 25b, relative to shaft 24 of module 22a. The movement may be on the order of single-digit microns or less in some implementations. Because the control system knows the locations of the test sites in the wafer, the control system knows how much to move module 22b. The movement may be in the X, Y, and/or Z dimensions in some examples.

As above, the location of test site 24b on wafer 14 is programmed into the control system in the configuration operation (54a) and, therefore, is the location that is expected to produce alignment between tester fiber optics 25b on module 22b and test site 26b. However, due to process variations in the wafer or other factors, the expected location that produces alignment may not be the correct location that produces alignment. Accordingly, the location of module 22b may be adjusted to bring module 22b at or close to the exact location that produces alignment, or at least into an alignment that enables optical testing to be performed on the SPD. The movement may be in the X, Y, and/or Z dimensions in some examples.

Following movement of module 22b to an expected location of test site 26n, the control system controls actuator 23 to cause module 22b to scan (54l) the local region around the expected location. As above, the local region may be tens (e.g., 20) of microns square or in area, or less in some implementations. The control system may control actuator 23 to move the second module 24b to implement the scanning. The scanning may include sinusoidal scanning and gradient scanning, which may be implemented using the techniques described with respect to module 22a. The scanning may include moving second module 24b around the scanning area, second module 24b outputting optical signals from tester fiber optics 25b during movement, tester fiber optics 25b receiving optical signals in response to the output optical signals, and the control system measuring optical power from the DUT that is produced based on the received optical signals in order to determine the power peak.

The control system may determine (54m) the location of the power peak by comparing newly-received optical powers to previously-received optical powers to identify which are greater. The power peak corresponds to the scanning location on the wafer having the greatest optical power. As above, the optical power scan results are obtained for discrete points 74 (FIG. 6), so the control system may perform interpolation among those points to determine (54g) the location of power peak 72.

Process 54 includes determining (54n) whether the peak optical power determined in operation 54m exceeds a predefined threshold, which may be the same threshold as, or a different threshold than, the threshold used in operation 54h. The control system may compare the peak optical power to the threshold in operation 54n. The threshold is programmed into the control system and may represent a minimum optical power needed to perform optical testing at SPD test site 24b. If the peak optical power determined in operation 54m does not exceed the predefined threshold, the control system determines (54o) whether the number of attempts at alignment have exceeded a predefined threshold. If the number of attempts at alignment have exceeded a predefined threshold, the control system determines (54p) that alignment has failed. In that case, manual intervention may be needed and/or system setting may be reprogrammed in operation 54a. If the number of attempts at alignment have not exceeded a predefined threshold (54o), the control system repeats operations 54k to 54o until the threshold is exceeded in operation 54n, meaning that peak optical power is sufficient for optical testing, or until the number of attempts at alignment have exceeded a predefined threshold in operation 54o.

If the peak optical power determined in operation 54m exceeds a predefined threshold (54n), this means that the location to which the second optical module 22b was moved in operation 54k brings tester fiber optics 25b into acceptable alignment with test site 26b to perform optical testing on SPD 12b. Accordingly, from this point forward in process 54, first module 22b remains stationary.

Process 54 stores (54q) values of the peak optical power with site-aware variables, such as the locations to which the first and second modules were moved. The control system may store this information in memory.

Process 54 may then perform testing (54r) on SPDs 12a and 12b. The testing may be parallel—for example, at least part of the testing of SPDs 12a and 12b may be concurrent. For example, the control system may control optical test instruments to send and receive optical signals concurrently from test sites 26a and 26b. The testing may be sequential—for example, one SPD 12a may be fully tested before the other SPD 12b. Test instruments, such as those described below, may output optical test signals over cables 30a, 30b, which reach the SPDs via the optical connection between tester fiber optics 25a, 25b and test sites 26a, 26b, respectively. Test instruments, such as those described below, may receive optical response signals over cables 30a, 30b, which reach the test instruments via the optical connection between tester fiber optics 25a, 25b and test sites 26a, 26b, respectively. The test instruments and/or control system may analyze the response signals to determine whether an SPD passed or failed testing. The testing may be performed automatically, e.g., without human intervention.

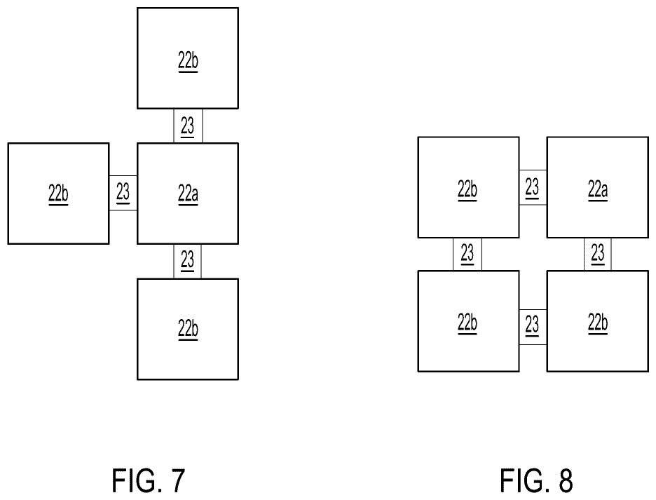

In some implementations, test system 10 may include multiple instances of module 22b. For example, a test system may include one, two, three, four, five, or move instances of module 22b. Each instance of module 22b may be physically coupled to module 22a, e.g., via an actuator, that is controllable to move that instance of module 22b relative to module 22a and thus relative to the SPD test sites to enable optical alignment of tester fiber optics to the test site. An example configuration containing four instances of module 22b is shown in FIG. 7.

In some configurations, actuators may be between instances of module 22b. For example, in FIG. 8, module 22a and instances of module 22b are physically coupled, for example, as part of a fiber optic unit. Instances of actuator 23 may be between instances of modules 22b rather than only between modules 22a and 22b. The positioning operations function the same. For example, after a module is optically aligned and stationary, the actuator connected to that module may be controlled to position an adjacent module relative to its corresponding SPD test site.

FIG. 9 is a block diagram showing example components of example automatic test equipment (ATE) 55 that includes a testing device/apparatus (referred to also as a “tester”) 56 and a control system 57.

ATE 55 includes probe head 59, examples of which is described with respect to FIG. 1 and elsewhere herein. Probe head 59 includes multiple test instruments 60a to 60n (where n>3), each of which may be configured, as appropriate, to implement and/or to control testing of DUTs such as SPDs. Although only four test instruments are shown, ATE 55 may include any appropriate number of test instruments, including one or more residing outside of probe head 59. The test instruments may connect to a backplane 61, which may include optical connector(s) that mate to optical connectors 39a, 39b of FIG. 1

The test instruments may be hardware devices that may each include one or more processing devices and/or circuitry 62 to implement and to control testing and memory 64 to store test data and or test programs to test SPDs. The test instruments may be configured—for example, programmed—to output test signals such as optical and/or electrical signals to test SPDs. The test signals to test the SPDs may be or include commands, instructions, data, parameters, variables, test vectors, and/or any other information designed to elicit response(s) from the SPD. The one or more processing devices 62 may also execute instructions to communicate with control system 57 and/or and to analyze responses to the test signals. The test instruments may be configured to perform parallel testing of different SPDs on a single wafer as described herein. In some implementations, the testing process may be automatic in that no human intervention is required to perform the parallel testing. Parallel testing may achieve a testing through put of 100 or more devices in under an hour; for example, 100 devices tested in about 50 minutes.

Probe card 65, examples of which are described with respect to FIG. 1 and elsewhere herein, may be electrically and mechanically connected to probe head 59. Probe card 65 may be controllable by one or more of the test instruments and/or the control system described below to make optical and electrical contact with SPDs on a wafer 70 held on chuck 71 to test the SPDs. Operation of individual components of the probe card, including modules 22a and 22b, may be controlled by one or more of test instruments 60a to 60n and/or by control system 57.

Control system 57 may be configured—e.g., programmed—to communicate with test instruments 60a to 60n to direct and/or to control testing of the DUTs. In some implementations, this communication 66 may be over a computer network or via a direct connection such as a computer bus or an optical medium. In some implementations, the computer network may be or include a local area network (LAN) or a wide area network (WAN). The control system may be or include a computing system comprised of one or more processing devices 67 (e.g., microprocessor(s)) and memory 69 for storing instructions to control operation of the ATE and/or testing. Memory 69 also stores one or more test programs 84 to execute and/or to send to the test instruments for execution. In this regard, control system 57 may be configured to provide test programs and/or test signals to test instruments 60a to 60n in the probe head, which the test instrument(s) use to test the SPD. Control system 57 may also be configured to receive SPD response signals (e.g., measurement data) from the test instrument(s) and to determine whether the corresponding DUT has passed or failed testing.

In some implementations, the control functionality is centralized in processing device(s) 67. In some implementations, all or part of the functionality attributed to control system 57 may also or instead be implemented on a test instrument and/or all or part of the functionality attributed to one or more test instruments may also or instead be implemented on control system 57. For example, the control system may be distributed across processing device(s) on one or more of test instruments 60a to 60n.

All or part of the example systems and example processes described in this specification and their various modifications may be configured or controlled at least in part by one or more computers such as control system 57 using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a circuit, part, subroutine, or other unit suitable for use in a computing environment. A computer program can be deployed to be executed on one computer or on multiple computers at one site or distributed across multiple sites and interconnected by a network.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

As used herein, the terms “comprises,” “comprising,” “includes,” “including,” “has,” “having,” “contains,” “containing,” and any variations thereof, are intended to cover a non-exclusive inclusion, such that systems, techniques, apparatus, structures, processes, or other subject matter described or claimed herein that includes, has, or contains an element or list of elements does not include only those elements but can include other elements not expressly listed or inherent to such systems, techniques, apparatus, structures, processes or other subject matter described or claimed herein.

All examples described herein are non-limiting.

In the description and claims provided herein, the adjectives “first”, “second”, “third”, and the like do not designate priority or order unless context suggests otherwise. Instead, these adjectives may be used solely to differentiate the nouns that they modify.

Any mechanical, optical, or electrical connection herein may include a direct physical connection or an indirect connection that includes one or more intervening components. A connection between two electrically conductive components is an electrical connection unless context suggests otherwise. A connection between two optical components is an optical connection unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A test system comprising:
a probe card configured to contact a substrate comprising devices under test (DUTs), the substrate comprising a first test site and a second test site corresponding, respectively, to a first DUT and a second DUT;
a first module comprising a first fiber optic array configured to align to the first test site;
a second module comprising a second fiber optic array configured to align to the second test site;
a motion system configured to move the first module relative to the substrate in order to move the first fiber optic array towards alignment with the first test site; and
an actuator configured to move the second module relative to the first module in order to move the second fiber optic array towards alignment with the second test site.

2. The test system of claim 1, further comprising a fiber optic unit, the fiber optic unit comprising the first module and the second module, the fiber optic unit further comprising:
one or more additional modules comprising one or more additional respective fiber optic arrays; and
one or more additional actuators each configured to move a respective one of the one or more additional modules in order to move a respective fiber optic array towards alignment with a respective test site on the substrate.

3. The test system of claim 2, wherein the motion system is configured to move the fiber optic unit relative to the probe card to cause the first fiber optic array to contact the first test site and to cause the second fiber optic array to contact the second test site.

4. The test system of claim 1, wherein the motion system is configured to move the first module in six degrees of freedom comprising movement that is forward/backward (Y axis), up/down (Z axis), left/right (X-axis), yaw (Z-axis rotation), pitch (X axis rotation), and roll (Y axis rotation).

5. The test system of claim 1, wherein the actuator comprises a piezoelectric device connected between the first module and the second module.

6. The test system of claim 1, wherein the actuator is configured to move the second module in at least two degrees of freedom comprising movement that is forward/backward (Y axis) and left/right (X-axis).

7. The test system of claim 1, wherein the motion system is configured to move the first module to a resolution of 10 microns or less.

8. The test system of claim 1, wherein the actuator is configured to move the second module to a resolution of 10 microns or less.

9. The test system of claim 1, wherein the first module comprises one or more first fiber optic cables connected to the first fiber optic array; and
wherein the second module comprises one or more second fiber optic cables connected to the second fiber optic array.

10. The test system of claim 9, further comprising:
one or more test instruments in communication with the one or more first fiber optic cables and the one or more second fiber optic cables, the one or more test instruments being configured to test optical components at test sites on the substrate in parallel through the one or more first fiber optic cables and the more second fiber optic cables.

11. The test system of claim 1, further comprising:
a control system configured to execute a test program to control movement implemented by the motion system and the actuator.

12. A method performed using a test system, the method comprising:
(a) controlling a motion system to move a first module, the first module comprising a first fiber optic array configured to align to a first test site corresponding a first device under test (DUT) on a substrate;
(b) controlling the motion system to scan the first module relative to the first DUT to identify a first location on the first DUT that corresponds to a first optical power peak, the first location corresponding to the first test site on the first DUT;
(c) determining that the first optical power peak exceeds a predetermined threshold;
(d) controlling an actuator to scan a second module relative to the first module to identify a second optical power peak at a second location on a second DUT on the substrate, the second location corresponding to a second test site on the second DUT, the second module comprising a second fiber optic array configured to align to the second test site on the second DUT;
(e) determining that the second optical power peak exceeds a predetermined threshold; and
(f) performing optical testing on the first DUT and the second DUT in parallel by, concurrently, (i) communicating between the first fiber optic array and the first test site at or near the first location and (ii) communicating between the second fiber optic array and the second test site at or near the second location.

13. The method of claim 12, wherein scanning the first module and scanning the second module each comprises performing a scan based on a profile.

14. The method of claim 13, wherein the profile is sinusoidal and the scan comprises a sinusoidal scan.

15. The method of claim 12, wherein scanning the first module and scanning the second module each comprises performing a gradient scan.

16. The method of claim 12, wherein the first module and the second module are associated with a probe card, the probe card comprising an electrical connector configured to mate to a corresponding electrical connector on the first DUT;
wherein the method comprise controlling the probe card to move toward the substrate to cause the electrical connector on the probe card to mate to the corresponding electrical connector on the first DUT: and
wherein operations (a) to (f) are performed after the electrical connector on the probe card mates to the corresponding electrical connector on the first DUT.

17. The method of claim 12, wherein the first module and the second module are components of a fiber optic unit, and wherein the method further comprises:
positioning the fiber optic unit a predefined distance above the DUT.

18. The method of claim 12, wherein positioning comprises:
using one or more capacitive sensors to obtain a voltage corresponding to a distance of the fiber optic unit above the substrate; and
comparing the voltage obtained to the predefined voltage.

19. The method of claim 12, wherein operations (a) to (f) are performed automatically without human intervention.

20. The method of claim 12, further comprising:
controlling the motion system to move the first module toward alignment with the first location prior to performing operations (d), (e), and (f) ; and
controlling the actuator to move the second module toward alignment with the second location prior to performing operation (f).

21. The method of claim 19, further comprising, prior to performing operation (f):
controlling the motion system to move the first module and the second module towards the DUT so that the first fiber optic array is connected to the first test site and so that the second fiber optic array is connected to the second test site 22. The method of claim 12, further comprising:
storing, in memory and in parallel, values for the first peak optical power and the second peak optical power in association with one or more respective site-aware variables.
